(19) United States
(12) Patent Application Publication
(10) Pub. No.: US 2026/0068039 A1
(43) Pub. Date: Mar. 5, 2026

(54) ELECTRONIC DEVICE INCLUDING TRANSMISSION COMPONENT

(71) Applicant: Samsung Electronics Co., Ltd., Suwon-si (KR)

(72) Inventors: Seyoon CHEON, Suwon-si (KR); Sungwon PARK, Suwon-si (KR); Youngsun LEE, Suwon-si (KR)

(21) Appl. No.: 19/365,785

(22) Filed: Oct. 22, 2025

Related U.S. Application Data
(63) Continuation of application No. PCT/KR2025/013653, filed on Sep. 4, 2025.

(30) Foreign Application Priority Data
Sep. 4, 2024 (KR) 10-2024-0120366
Oct. 23, 2024 (KR) 10-2024-0146015

(51) Int. Cl. H05K 1/02; H01P 3/08; H01Q 1/22

(52) U.S. Cl. CPC H05K 1/0277; H01P 3/081; H01Q 1/22; H05K 1/0243; H05K 2201/10098

(57) ABSTRACT

A transmission component is provided. The transmission component includes a flexible printed circuit board including a first signal transmission section, a second signal transmission section, and a signal transmission route changing section, a first signal line provided on a first surface of the flexible printed circuit board, a first ground provided on a second surface of the flexible printed circuit board, a second signal line provided on the first surface of the flexible printed circuit board, a third signal line provided on the second surface of the flexible printed circuit board, a fourth signal line provided on the second surface of the flexible printed circuit board, and a second ground provided on the first surface of the flexible printed circuit board.

### CROSS-REFERENCE TO RELATED APPLICATION(S)

This application is a continuation application, claiming priority under 35 U.S.C. § 365 (c), of an International application No. PCT/KR2025/013653, filed on Sep. 4, 2025, which is based on and claims the benefit of a Korean patent application number 10-2024-0120366, filed on Sep. 4, 2024, in the Korean Intellectual Property Office, and of a Korean patent application number 10-2024-0146015, filed on Oct. 23, 2024, in the Korean Intellectual Property Office, the disclosure of each of which is incorporated by reference herein in its entirety.

### BACKGROUND

### 1. Field

The disclosure relates to an electronic device including a transmission component.

### 2. Description of Related Art

Transmission components which use via structures may implement an electric connection between different layers in a multilayer printed circuit board or an integrated circuit. A transmission component which use the via structure may be route through which high frequency signals move through via when transferred to a different layer of the multilayer printed circuit board. Through via, signal integrity, impedance matching, and signal reflection may be managed.

The above-described information may be provided as related art for the purpose of aiding in the understanding of the disclosure. No claim or determination is made in any way with respect to whether any of the above-described description may be applied as prior art associated with the disclosure.

### SUMMARY

Aspects of the disclosure are to address at least the above-mentioned problems and/or disadvantages and to provide at least the advantages described below. Accordingly, an aspect of the disclosure is to provide an electronic device including a transmission component.

Additional aspects will be set forth in part in the description which follows and, in part, will be apparent from the description, or may be learned by practice of the presented embodiments.

In accordance with an aspect of the disclosure, a transmission component is provided. The transmission component includes a flexible printed circuit board including a first signal transmission section, a second signal transmission section, and a signal transmission route changing section disposed between the first signal transmission section and the second signal transmission section, a first signal line provided on a first surface of the flexible printed circuit board and disposed in the first signal transmission section, a first ground provided on a second surface opposite to the first surface of the flexible printed circuit board and disposed in the first signal transmission section, a second signal line provided on the first surface of the flexible printed circuit board to be disposed in the signal transmission route change section, wherein one end of the second signal line is connected to the first signal line, a third signal line provided on the second surface of the flexible printed circuit board to be disposed in the signal transmission route change section, wherein one end of the third signal line is connected to the first ground, a fourth signal line provided on the second surface of the flexible printed circuit board to be disposed in the second signal transmission section, wherein one end of the fourth signal line is connected to other end of the third signal line, and a second ground provided on the first surface of the flexible printed circuit board to be disposed in the second signal transmission section, wherein one end of the second ground is connected to other end of the second signal line.

In accordance with another aspect of the disclosure, an electronic device is provided. The electronic device includes a housing, an antenna, and a transmission component including a flexible printed circuit board on which an antenna is disposed and which is divided into a first signal transmission section disposed at one side of the antenna, a signal transmission route changing section disposed at one side of the first signal transmission section, and a second signal transmission section disposed at one side of the signal transmission route changing section, wherein each of the first signal transmission section and the second signal transmission section include a first microstrip line structure, and wherein the signal transmission route changing section includes a parallel-plate waveguide structure which supports a transverse electromagnetic (TEM) mode.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device capable of performing operations according to an embodiment of the disclosure;

FIG. 2 is a diagram illustrating an electronic device including and disposed with a transmission component according to an embodiment of the disclosure;

FIG. 3 is a diagram illustrating a transmission component and is a cross-sectional view taken along line A-A′ shown in FIG. 2 according to an embodiment of the disclosure;

FIG. 4 is a perspective diagram illustrating a transmission component according to an embodiment of the disclosure;

FIG. 5 is a side view illustrating a transmission component according to an embodiment of the disclosure;

FIG. 6 is a plane view illustrating a transmission component according to an embodiment of the disclosure;

FIG. 7 is a diagram illustrating a cross-sectional view taken along line B-B′ shown in FIG. 6 according to an embodiment of the disclosure;

FIG. 8 is a diagram illustrating a cross-sectional view taken along line C-C′ shown in FIG. 6 according to an embodiment of the disclosure;

FIG. 9 is a diagram illustrating a cross-sectional view taken along line D-D′ shown in FIG. 6 according to an embodiment of the disclosure;

FIG. 10 is a graph illustrating a relationship between a length of a signal transmission route changing section of a transmission component and a wavelength range of a target frequency according to an embodiment of the disclosure;

FIG. 11 is a plane view illustrating a transmission component according to an embodiment of the disclosure;

FIG. 12 is a plane view illustrating a transmission component according to an embodiment of the disclosure;

FIG. 13 is a graph illustrating a comparison of insertion loss between a transmission component and a transmission component applied with via according to an embodiment of the disclosure;

FIG. 14 is a plane view illustrating a transmission component according to an embodiment of the disclosure;

FIG. 15 is a plane view illustrating a transmission component according to an embodiment of the disclosure;

FIG. 16 is a plane view illustrating a transmission component according to an embodiment of the disclosure;

FIG. 17 is a diagram illustrating an example of an antenna being connected to a transmission component through a connector according to an embodiment of the disclosure;

FIG. 18 is a diagram illustrating an example of a back surface cover being coupled to a housing of an electronic device according to an embodiment of the disclosure;

FIG. 19 is a diagram illustrating a cross-sectional view taken along line E-E′ shown in FIG. 18 according to an embodiment of the disclosure; and

FIG. 20 is a diagram illustrating an example in which an antenna and a wireless charging coil portion are disposed together on a flexible printed circuit board included in a transmission component of an electronic device according to an embodiment of the disclosure.

Throughout the drawings, it should be noted that like reference numbers are used to depict the same or similar elements, features, and structures.

### DETAILED DESCRIPTION

Various modifications may be made to the embodiments of the disclosure, and there may be various types of embodiments. Accordingly, specific embodiments will be illustrated in drawings, and the embodiments will be described in detail in the detailed description. However, it should be noted that the various embodiments are not for limiting the scope of the disclosure to a specific embodiment, but should be interpreted to include all modifications, equivalents or alternatives of the embodiments included in the ideas and the technical scopes disclosed herein. With respect to the description of the drawings, like reference numerals may be used to indicate like elements.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In describing the disclosure, in case it is determined that the detailed description of related known technologies may unnecessarily confuse the gist of the disclosure, the detailed description thereof will be omitted. Further, one or more embodiments according to the disclosure may be modified to various different forms, and it is to be understood that the scope of the technical spirit of the disclosure is not limited to the embodiments below. Rather, the embodiments are provided so that the disclosure will be thorough and complete, and to fully convey the technical spirit of the disclosure to those skilled in the art.

Terms used in the disclosure are merely used to describe a specific embodiment of the disclosure, and is not intended to limit the scope of protection.

In the disclosure, expressions, such as “have”, “may have”, “include”, and “may include” are used to designate a presence of a corresponding characteristic (e.g., elements, such as numerical value, function, operation, or component), and not to preclude a presence or a possibility of additional characteristics.

In the disclosure, expressions, such as “A or B”, “at least one of A and/or B”, or “one or more of A and/or B” may include all possible combinations of the items listed together. For example, “A or B”, “at least one of A and B”, or “at least one of A or B” may refer to all cases including (1) at least one A, (2) at least one B, or (3) both of at least one A and at least one B.

Expressions, such as “1^{st}”, “2^{nd}”, “first”, or “second” used in the disclosure may limit various elements regardless of order and/or importance, and may be used merely to distinguish one element from another element and not limit the relevant element.

The expression “configured to . . . (or set up to)” used in the disclosure may be used interchangeably with, for example, “suitable for . . . ”, “having the capacity to . . . ”, “designed to . . . ”, “adapted to . . . ”, “made to . . . ”, or “capable of . . . ” based on circumstance. The term “configured to . . . (or set up to)” may not necessarily mean “specifically designed to” in terms of hardware.

In the disclosure, the term ‘module’ or ‘part’ may perform at least one function or operation, and may be implemented with a hardware or software, or implemented with a combination of hardware and software. In addition, a plurality of ‘modules’ or a plurality of ‘parts’, except for a ‘module’ or a ‘part’ which needs to be implemented with a specific hardware, may be integrated in at least one module and implemented as at least one processor.

Meanwhile, the various elements and areas of the drawings have been schematically illustrated. Accordingly, the technical spirit of the disclosure is not limited by relative sizes and distances illustrated in the accompanied drawings.

One or more embodiments of the disclosure will be described with reference to the accompanying drawings to aid in the understanding of those of ordinary skill in the art.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

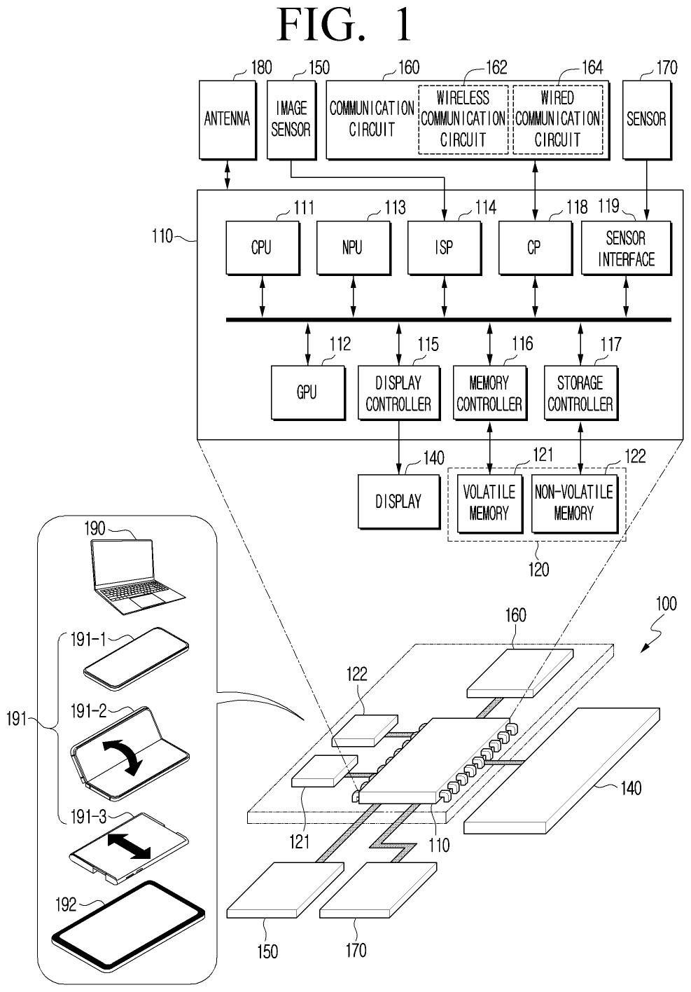

FIG. 1 is a block diagram of an electronic device capable of performing operations according to an embodiment of the disclosure.

Referring to FIG. 1, an electronic device 100 may be one from among various forms of electronic devices, such as a notebook 190, smartphones 191 having various form factors (e.g., a bar-type smartphone 191-1, a foldable-type smartphone 191-2, or a slideable-type (or rollable-type) smartphone 191-3), a tablet 192, a cellular phone (not shown), and other similar computing devices (not shown). Elements, relationships thereof, and functions thereof shown in FIG. 1 are merely examples, and embodiments described or claimed in the disclosure are not limited by the above. The electronic device 100 may be referred to as a mobile device, a user device, a multi-function device, a mobile device, or a server.

The electronic device 100 may include elements including at least one processor 110 (hereinafter, referred to as a ‘processor 110’), at least one memory 120 (hereinafter, referred to as ‘memory 120’), at least one display 140 (hereinafter, referred to as a ‘display 140’), at least one image sensor 150 (hereinafter, referred to as an ‘image sensor 150’), at least one communication circuit 160 (hereinafter, referred to as a ‘communication circuit 160’), and/or at least one sensor 170 (hereinafter, referred to as a ‘sensor 170’). The elements above are merely examples. For example, the electronic device 100 may include other elements (e.g., a power management integrated circuitry (PMIC), an audio processing circuit, an antenna, a rechargeable battery, or an input and output interface). For example, a portion of the elements may be omitted from the electronic device 100. For example, some of the elements may be integrated into one element.

The processor 110 may be implemented with one or more integrated circuit (or circuitry) (IC) chips, and may execute variety of data processing. The processor 110 may include at least one electrical circuit, and individually or collectively perform distributed processing of instructions (or programs, data) stored in the memory 120. The processor 110 may include a processor assembly including one or more processing circuits. The processor 110 may include any operative processing circuit to control performance and operations of one or more elements (e.g., the memory 120, the display 140, the image sensor 150, the communication circuit 160, and/or the sensor 170) of the electronic device 100. For example, the processor 110 (e.g., an application processor (AP)) may be implemented as a system on chip (SoC) (e.g., one chip or a chip set). For example, the processor 110 may be implemented as a plurality of cores (or at least one core circuit), a plurality of chips, or a plurality of chip sets. For example, the processor 110 may include one or more processing circuits. For example, the processor 110 may include one or more processing circuits configured to individually and/or collectively perform several functions of the disclosure. In an unlimited example, at least a portion of the processor 110 may be included in a first chip of the electronic device 100, and at least another portion of the processor 110 may be included in a second chip of the electronic device 100 different from the first chip of the electronic device 100.

For example, the processor 110 may include a central processing unit (CPU) 111, a graphics processing unit (GPU) 112, a neural processing unit (NPU) 113, an image signal processor (ISP) 114, a display controller 115, memory controller 116, a storage controller 117, a communication processor (CP) 118, and/or a sensor interface 119. The elements of the processor 110 described above are merely examples. For example, the processor 110 may further include other elements. For example, some elements of the processor 110 may be omitted from the processor 110. For example, some elements of the processor 110 may be included as separate elements of the electronic device 100 outside of the processor 110. For example, a portion of the elements (e.g., the memory controller 116) of the processor 110 may be included in other elements (e.g., at least a portion of the memory 120, an interface (e.g., useable to connect to at least one element of the electronic device 100), the display 140, and/or the image sensor 150).

The processor 110 may cause other elements of the electronic device 100 to perform various operations by executing the instructions stored in the memory 120. The CPU 111 (or a central processing circuit) may be configured to control elements of the processor 110 based on the execution of instructions stored in the memory 120 (e.g., volatile memory 121 and/or non-volatile memory 122). The GPU 112 (or a graphics processing circuit) may be configured to execute parallel computations (e.g., a rendering). The NPU 113 (or a neural processing circuit, or an artificial intelligence (AI) chip) may be configured to execute computations (e.g., a convolution computation) for an artificial intelligence model. The ISP 114 (or an image signal processing circuit) may be configured to process a raw image obtained through the image sensor 150 in a format suitable for elements in the electronic device 100 or elements of the processor 110. The display controller 115 (or a display control circuit, or a display processing unit (DPU)) may be configured to process an image obtained from the CPU 111, the GPU 112, the ISP 114, or the memory 120 (e.g., volatile memory 121) in a format suitable for the display 140. The memory controller 116 (or memory control circuit) may be configured to control the reading of data from the volatile memory 121 and the recording of data in the volatile memory 121. The storage controller 117 (or a storage control circuit) may be configured to control the reading of data from the non-volatile memory 122 and the recording of data in the non-volatile memory 122. The CP 118 (or a communication processing circuit) may be configured to process data obtained from the elements of the processor 110 in a format suitable for transmitting to another electronic device through the communication circuit 160, or process data obtained from another electronic device through the communication circuit 160 in a format suitable for processing elements of the processor 110. For example, the communication circuit 160 may include one or more communication circuits. The sensor interface 119 (or a sensing data processing circuit, a sensor hub) may be configured to process data on a state of the electronic device 100 and/or a state surrounding the electronic device 100 obtained through the sensor 170 in a format suitable for elements of the processor 110.

The memory 120 may include one or more storage media (or one or more storage devices). For example, the memory 120 may include memory assembly including one or more storage media. For example, the one or more storage media may include permanent memory (e.g., non-volatile memory 122), such as a hard drive, flash memory, or read-only memory (ROM), semi-permanent memory (e.g., volatile memory 121), such as random access memory (RAM), any other suitable type of storage (or a storage assembly), or any combination thereof. The memory 120 may include cache memory which is memory of one or more different types used to temporarily store data for functions or features of the electronic device 100. As an unlimited example, the cache memory may be included in the processor 110. The memory 120 may be fixedly embedded in the electronic device 100, or incorporated onto one or more suitable types of components (e.g., a subscriber identify module (SIM) card and/or a secure digital (SD) card) which can be inserted into the electronic device 100 or removed from the electronic device 100 repeatedly.

For example, the memory 120 may store one or more software applications, such as an operating system (or system) software application, a firmware software application, a driver software application, a plug-in (e.g., an add-in, an add-on, and/or an applet) software application, and/or any other suitable software applications. For example, the one or more software applications may include instructions executable by the processor 110. For example, the memory 120 may store instructions callable by an application programming interface (API). For example, the memory 120 may store instructions within a library.

The communication circuit 160 may support establishing a direct (e.g., a wired) communication channel or a wireless communication channel between the electronic device 100 and an external electronic device (e.g., another electronic device (not shown) or a server (not shown)), and performing communication through the established communication channel. The communication circuit 160 may include one or more communication processors which are operated independently from the processor 110 (e.g., application processor), and which support a direct (e.g., a wired) communication or a wireless communication. According to an embodiment of the disclosure, the communication circuit 160 may include a wireless communication circuit 162 (e.g., a cellular communication circuit, a short range wireless communication circuit, or a global navigation satellite system (GNSS) communication circuit) or a wired communication circuit 164 (e.g., a local area network (LAN), or a low-power communication circuit). A relevant communication circuit from among the communication circuits described above may communicate with an external electronic device (not shown) through a first network (e.g., a short-range communication network, such as Bluetooth, wireless fidelity (WiFi) direct, or infrared data association (IrDA)) or a second network (e.g., a long-range communication network, such as a legacy cellular network, a 5G network, a next generation communication network, Internet, or a computer network (e.g., LAN or wide area network (WAN))). The several types of communication circuits may be integrated into one element (e.g., a single chip), or implemented as a plurality of elements (e.g., plurality of chips) separate from one another. The wireless communication circuit 162 may check or verify the electronic device 100 within a communication network, such as the first network or the second network using subscriber information (e.g., international mobile subscriber identity (IMSI)) stored in a subscriber identification module (not shown).

The wireless communication circuit 162 may support 5G network after 4G network and next generation communication technology, such as, for example, a new radio (NR) access technology. The NR access technology may support high-speed transmission of high-volume data (enhanced mobile broadband (eMBB)), terminal power minimization and connection of plurality of terminals (massive machine type communications (mMTC)), or ultra-reliability and low-latency (ultra-reliable and low-latency communications (URLLC)). The wireless communication circuit 162 may support, for example, a high-frequency band (e.g., mm Wave band) in order to achieve high data transmission rate.

The wireless communication circuit 162 may support various technologies, such as, for example, beamforming, massive multiple-input and multiple-output (MIMO), full dimensional MIMO (FD-MIMO), array antenna, analog beam-forming, or large scale antenna technologies to secure performance in the high-frequency band. The wireless communication circuit 162 may support various requirements defined by the electronic device 100 and an external electronic device (e.g., another electronic device or a network system (e.g., second network)). According to an embodiment of the disclosure, the wireless communication circuit 162 may support peak data rate (e.g., greater than or equal to 20 Gbps) for eMBB realization, loss coverage (e.g., about less than or equal to 164 dB) for mMTC realization, or U-plane latency (e.g., less than or equal to 0.5 ms for each of down-link (DL) and up-link (UL), or less than or equal to 1 ms round trip) for URLLC realization.

An antenna module 180 may transmit signals or power to the outside (e.g., an external electronic device) or receive the same from the outside. According to an embodiment of the disclosure, the antenna module 180 may include a conductor formed on a printed circuit board (e.g., PCB) or an antenna including a radiator formed with conductive patterns. According to an embodiment of the disclosure, the antenna module 180 may include a plurality of antennas (e.g., array antenna). In this case, at least one antenna suitable to a communication method used in the communication network, such as the first network or the second network may be selected from the plurality of antennas by, for example, the communication circuit 160. Signals or power may be transmitted or received between the communication circuit 160 and an external electronic device through the selected at least one antenna. According to an embodiment of the disclosure, other components (e.g., a radio frequency integrated circuit (RFIC)) other than the radiator may be additionally formed as a part of the antenna module 180.

According to various embodiments of the disclosure, the antenna module 180 may form an mm Wave antenna module. According to an embodiment of the disclosure, the mm Wave antenna module may include the RFIC which is disposed on the printed circuit board, or on a first surface (e.g., a bottom surface) of the printed circuit board or adjacently thereto, and which is capable of supporting a designated high frequency band (e.g., mm Wave band), and a plurality of antennas (e.g., array antenna) which is disposed on a second surface (e.g., a top surface or a side surface) of the printed circuit board or adjacently thereto and which is capable of transmitting or receiving signals in the designated high frequency band.

At least a portion of the elements may be interconnected through communication methods between peripheral devices (e.g., BUS, general purpose input and output (GPIO), serial peripheral interface (SPI), or mobile industry processor interface (MIPI)) and may exchange signals (e.g., commands or data) between one another.

According to an embodiment of the disclosure, commands or data may be transmitted or received between the electronic device 100 and external electronic devices (not shown) through a server (not shown) connected to the second network. Each of the external electronic devices (not shown) may be devices of same or different types from the electronic device 100. According to an embodiment of the disclosure, all or a portion of operations executed in the electronic device 100 may be executed in one or more external electronic devices from among the external electronic devices (not shown). For example, if the electronic device 100 has to perform any function or service automatically, or in response to a request by a user or from another device, the electronic device 100 may request to one or more external electronic devices to perform at least a portion of the function or the service instead of or in addition to executing the functions or services on its own. The one or more external electronic devices that received the above request may execute at least a portion of the requested function or service, or an additional function or service associated with the request, and transfer a result of the execution to the electronic device 100.

The electronic device 100 may process the result as is or additionally, and provide as at least a portion of a response to the above request. To this end, cloud computing, distributed computing, mobile edge computing (MEC), or client-server computing technologies may be used as an example. The electronic device 100 may provide an ultra-low latency service using, for example, distributed computing or mobile edge computing. The electronic device 100 may be applied to intelligent service (e.g., smart home, smart city, smart car, or health care) based on 5G communication technology and IoT related technologies.

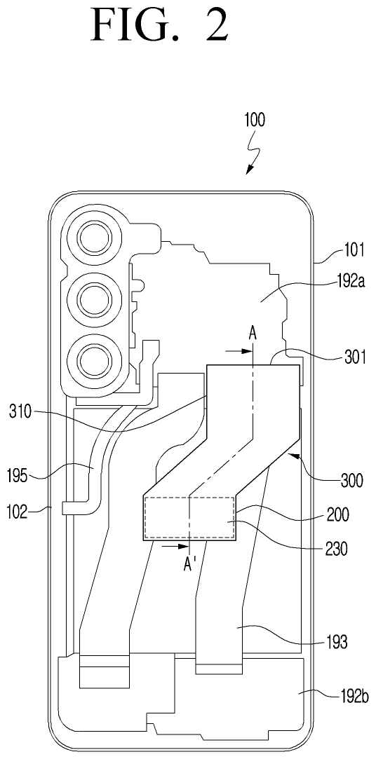

FIG. 2 is a diagram illustrating an electronic device including a transmission component according to an embodiment of the disclosure.

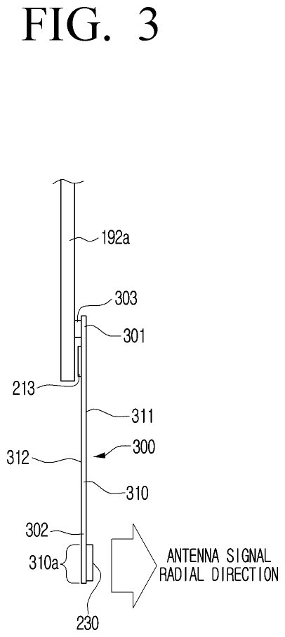

FIG. 3 is a diagram illustrating a transmission component and is a cross-sectional view taken along line A-A′ shown in FIG. 2 according to an embodiment of the disclosure.

Referring to FIGS. 2 and 3, a transmission component 300 according to an embodiment of the disclosure may be included in the electronic device 100 to transmit signals between a first printed circuit board 192a and an antenna 230. The transmission component 300 may have a first side portion 301 connected to the first printed circuit board 192a.

For example, at the first side portion 301 of the transmission component 300, a connector 303 which is electrically connected with the first printed circuit board 192a may be provided. At the first side portion 301 of the transmission component 300, circuitry (e.g., a radio frequency integrated circuit (RF IC) 213) may be disposed. In this case, the connector 303 and/or RF IC 213 may be provided on the first printed circuit board 192a.

For example, at a second side portion 302 of the transmission component 300, the antenna 230 may be disposed. In this case, the antenna 230 may be disposed at a portion extended from one side 200 of the transmission component 300. The extended portion of the transmission component 300 may be one portion 310a (referring to FIG. 3) of a flexible printed circuit board 310 included in the transmission component 300.

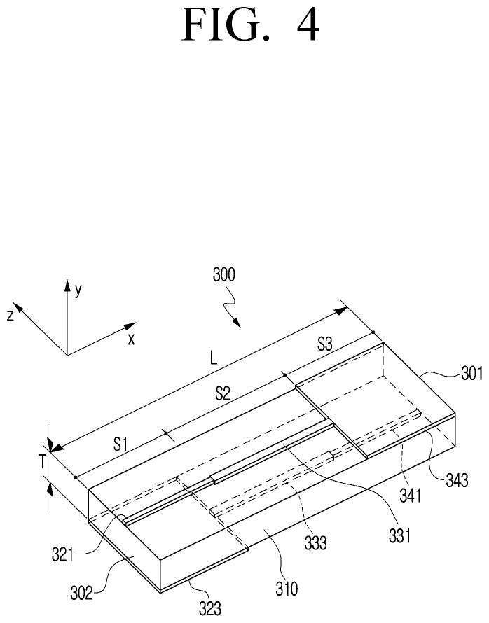

The antenna 230 may be electrically connected with a first signal line 321 (referring to FIG. 4) of the transmission component 300. For example, the antenna 230 may be formed with a conductive metal having a defined pattern. The antenna 230 may have a substantially same thickness and/or material as the first signal line 321. For example, the antenna 230 may be an mm Wave antenna.

According to an embodiment of the disclosure, the transmission component 300 may include the flexible printed circuit board 310. The RF IC 213 may strongly amply weak GHz band signals received from the mm Wave antenna 230. For example, the RF IC 213 may perform modulation which involves carrying data received from a first printed circuit board 192a in a wireless frequency and transmitting to the mmWave antenna 230, demodulation which involves restoring data from signals received from the mm Wave antenna 230, filtering which involves passing only signals of a specific frequency band and removing the remaining unnecessary signals, frequency conversion which involves converting the frequency of signals and moving to a suitable band, and oscillation which involves generating a signal of a specific frequency and using as a reference signal of a transmitter or a receiver. A position for disposing the RF IC 213 is not limited to the flexible printed circuit board 310, and may be disposed on the first printed circuit board 192a. The mm Wave antenna 230 may use an mm Wave frequency band (e.g., 30 GHz-300 GHz). For example, the mmWave antenna 230 may provide a high bandwidth for 5G communication making it possible for ultra-high-speed data transmission.

According to an embodiment of the disclosure, the position for disposing the connector 303 and the RF IC 213 may be positioned on a second surface 312 of the flexible printed circuit board 310 which faces a side of the first printed circuit board 192a. The position for disposing the connector 303 and the RF IC 213 is not limited to the flexible printed circuit board 310, and may be positioned on the first printed circuit board 192a.

The transmission component 300 according to an embodiment of the disclosure may transfer inter-layer signals between the RF IC 213 and the mmWave antenna 230 while reducing insertion loss.

According to an embodiment of the disclosure, the transmission component 300 may transfer signals (e.g., signals in the mmWave frequency band) between the RF IC 213 and the mm Wave antenna 230 at a low loss. For example, the transmission component which uses via may have loss greatly increase in high frequencies due to properties of material and incompleteness in process, and performance may be deteriorated due to distortion and reflection of signals occurring in high frequencies due to an impedance mismatch. The transmission component 300 according to an embodiment of the disclosure may effectively operate in high frequencies (e.g., from several GHz to tens of GHz, up to mm Wave bands) due to very low transmission loss.

The electronic device 100 as shown in FIG. 2 may have the first printed circuit board 192a and a second printed circuit board 192b disposed at a constant interval from the first printed circuit board 192a connected by a connection member 193. The connection member 193 may transmit signals between the first printed circuit board 192a and the second printed circuit board 192b. For example, the first printed circuit board 192a and/or the second printed circuit board 192b may be a flexible printed circuit board. In this case, the transmission component 300 according to an embodiment of the disclosure may be included in a portion of a section of the connection member 193 which connects the first printed circuit board 192a and/or the second printed circuit board 192b.

For example, the electronic device 100 may include an antenna 102 which uses a frame that is a part of a housing 101 formed of metal as a radiator, and a connection member 195 which transmits high frequency signals between the antenna 102 and the first printed circuit board 192a. For example, the connection member 195 may be a flexible printed circuit board. The transmission component 300 according to an embodiment of the disclosure may be applied at the connection member 195.

The transmission component 300 according to an embodiment of the disclosure will be described below with reference to the drawings.

FIG. 4 is a perspective diagram illustrating a transmission component according to an embodiment of the disclosure.

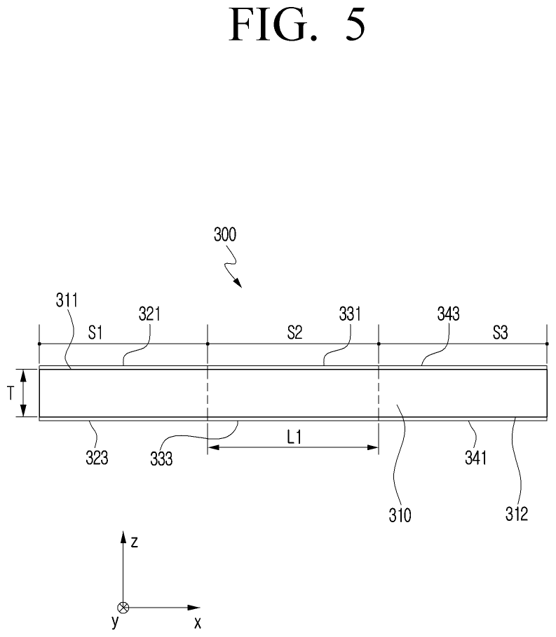

FIG. 5 is a perspective diagram illustrating a transmission component according to an embodiment of the disclosure.

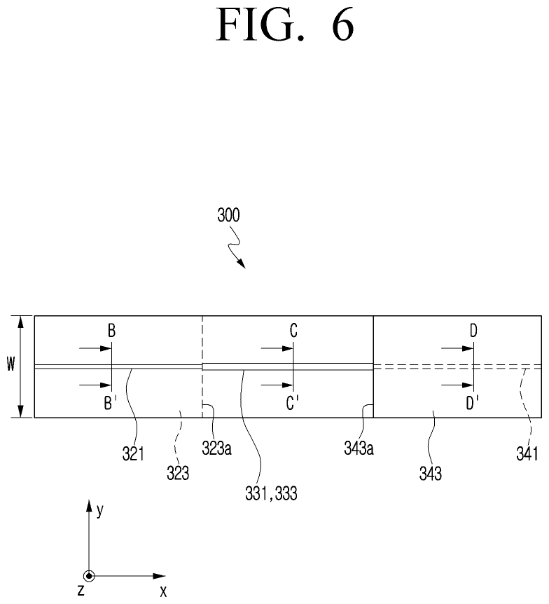

FIG. 6 is a perspective diagram illustrating a transmission component according to an embodiment of the disclosure.

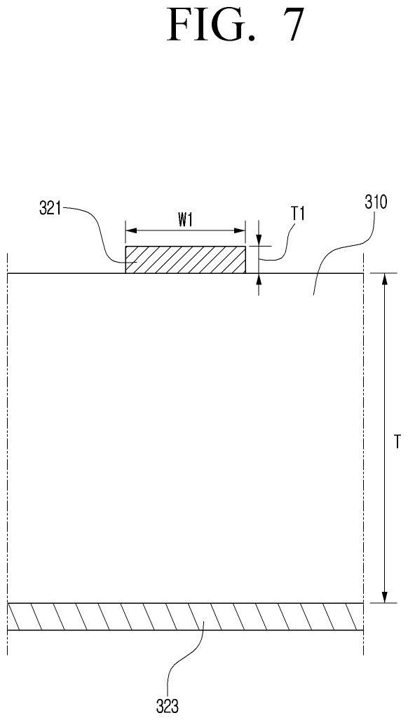

FIG. 7 is a diagram illustrating a cross-sectional view taken along line B-B′ shown in FIG. 6 according to an embodiment of the disclosure.

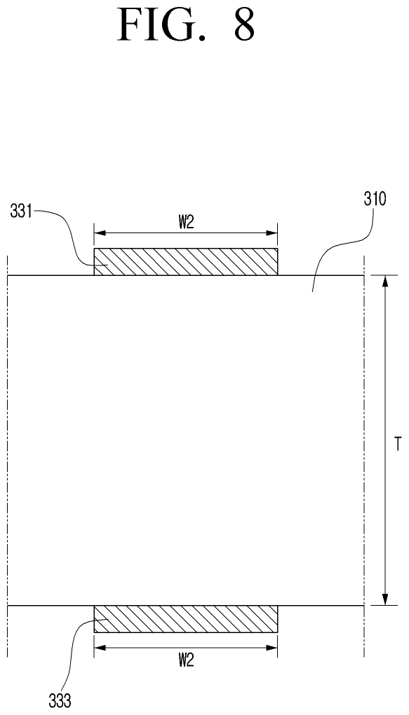

FIG. 8 is a diagram illustrating a cross-sectional view taken along line C-C′ shown in FIG. 6 according to an embodiment of the disclosure.

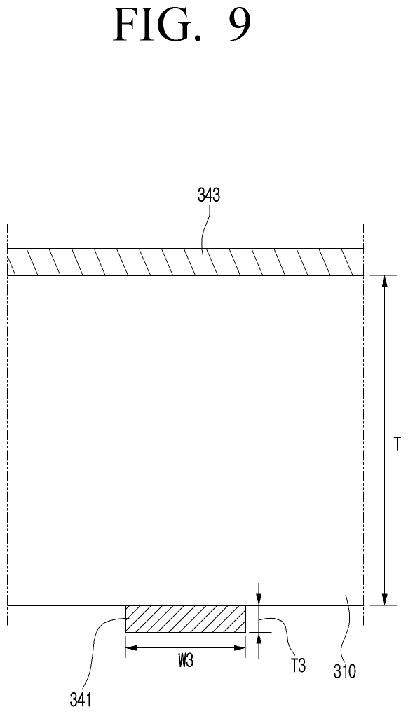

FIG. 9 is a diagram illustrating a cross-sectional view taken along line D-D′ shown in FIG. 6 according to an embodiment of the disclosure.

Referring to FIGS. 4, 5, and 6, the flexible printed circuit board 310 included in the transmission component 300 according to an embodiment of the disclosure may include a first signal transmission section S1, a signal transmission route changing section S2, and a second signal transmission section S3. The first signal transmission section S1 may have signals flowing along a first layer of the transmission component 300 (e.g., a first surface 311 of the flexible printed circuit board 310). The second signal transmission section S3 may have signals flowing along a second layer of the transmission component 300 (e.g., a second surface 312 of the flexible printed circuit board 310).

The signal transmission route changing section S2 may be positioned between the first signal transmission section S1 and the second signal transmission section S3. The signal transmission route changing section S2 may transmit signals, which flow from the second side portion 302 of the transmission component 300 to the signal transmission route changing section S2 along the first layer of the transmission component 300, to the second layer of the transmission component 300. The signal transmission route changing section S2 may transmit signals, which flow from the first side portion 301 of the transmission component 300 to the signal transmission route changing section S2 along the second layer of the transmission component 300, to the first layer of the transmission component 300.

For example, the flexible printed circuit board 310 of the transmission component 300 may be a dielectric layer having a determined thickness. In the disclosure, a dielectric layer 310 may be referred to as the flexible printed circuit board 310. Accordingly, a first side portion 301 of the dielectric layer 310 may be referred to as the first side portion 301 of the flexible printed circuit board 310, a second side portion 302 of the dielectric layer 310 may be referred to as the second side portion 302 of the flexible printed circuit board 310, a first surface 311 of the dielectric layer 310 may be referred to as the first surface 311 of the flexible printed circuit board 310, and a second surface 312 of the dielectric layer 310 may be referred to as the second surface 312 of the flexible printed circuit board 310.

The transmission component 300 may include the dielectric layer 310, the first signal line 321, a first ground 323, a second signal line 331, a third signal line 333, a fourth signal line 341, and a second ground 343.

For example, the dielectric layer 310 may have a length L corresponding to a total of a length of the first signal transmission section S1, a length of the signal transmission route changing section S2, and a length of the second signal transmission section S3. The dielectric layer 310 may have a same thickness T for all of the first signal transmission section S1, the signal transmission route changing section S2, and the second signal transmission section S3. The thickness T of the dielectric layer 310 may affect propagation characteristics (e.g., propagation velocity of electromagnetic waves, characteristic impedances, and loss) in the signal transmission route changing section S2.

According to an embodiment of the disclosure, the first signal line 321 and the first ground 323 may be provided in the first signal transmission section S1. The first signal line 321 may be disposed along a length direction (e.g., x-axis direction in FIG. 6) of the dielectric layer 310 on the first surface 311 of the dielectric layer 310. The first signal line 321 may be formed of a conductive metal. For example, one end of the first signal line 321 may be electrically connected to the mmWave antenna 230 (referring to FIG. 3) disposed at the second side portion 302 of the dielectric layer 310.

According to an embodiment of the disclosure, the first ground 323 may be disposed on the second surface 312 of the dielectric layer 310. For example, the first ground 323 may roughly have a same width as a width W of the dielectric layer 310. A front end 323a of the first ground 323 may be a boundary of the first signal transmission section S1 and the signal transmission route changing section S2. For example, the front end 323a of the first ground 323 may be disposed approximately perpendicular to the length direction (e.g., x-axis direction in FIG. 6) of the dielectric layer 310.

According to an embodiment of the disclosure, the first signal transmission section S1 may have a microstrip structure due to the first signal line 321 having a narrow width and the first ground 323 having a significantly wider width than the first signal line 321 being disposed with the dielectric layer 310 therebetween. For example, if a width W1 of the first signal line 321 is about 180 μm, a width of the first ground 323 may be about 6 mm (6000 μm).

According to an embodiment of the disclosure, the fourth signal line 341 and the second ground 343 may be provided in the second signal transmission section S3. The fourth signal line 341 may be disposed along the length direction (e.g., x-axis direction in FIG. 6) of the dielectric layer 310 on the second surface 312 of the dielectric layer 310. The fourth signal line 341 may be formed of a conductive metal. For example, one end of the fourth signal line 341 may be electrically connected with the connector 303 disposed at the first side portion 301 of the dielectric layer 310. For example, the fourth signal line 340 may be electrically connected with the RF IC 213 (referring to FIG. 3), and the RF IC 213 (referring to FIG. 3) may be electrically connected with the connector 303.

According to an embodiment of the disclosure, the second ground 343 may be disposed on the first surface 311 of the dielectric layer 310. The second ground 343 may roughly have a same width as the width W of the dielectric layer 310. A front end 343a of the second ground 343 may be a boundary of the signal transmission route changing section S2 and the second signal transmission section S3. The front end 343a of the second ground 343 may be disposed approximately perpendicular to the length direction (e.g., x-axis direction in FIG. 6) of the dielectric layer 310.

According to an embodiment of the disclosure, the second signal transmission section S3 may have the microstrip structure due to the fourth signal line 341 having a narrow width and the second ground 343 having a significantly wider width than the fourth signal line 341 being disposed with the dielectric layer 310 therebetween. For example, if a width W3 of the fourth signal line 341 is about 180 μm, a width of the second ground 343 may be about 6 mm (6000 μm).

According to an embodiment of the disclosure, the second ground 343 and the third signal line 333 may be provided in the signal transmission route changing section S2. The second signal line 331 may be disposed along the length direction (e.g., x-axis direction in FIG. 6) of the dielectric layer 310 on the first surface 311 of the dielectric layer 310. The third signal line 333 may be disposed to be in parallel with the second signal line 331 on the second surface 312 of the dielectric layer 310. In this case, the second signal line 331 and the third signal line 333 may be aligned to correspond to each other on the first and second surfaces 311 and 312 of the dielectric layer 310.

According to an embodiment of the disclosure, the signal transmission route changing section S2 may have a parallel-plate waveguide structure which supports a transverse electromagnetic mode (TEM mode) due to the dielectric layer 310 being disposed between the second signal line 331 and the third signal line 333. In the TEM mode, an electric field is arranged in a direction perpendicular (e.g., z-axis direction in FIG. 5) to a direction of progress (e.g., x-axis direction in FIG. 6) of the waveguide and a magnetic field is arranged in a direction perpendicular (e.g., y-axis direction in FIG. 6) to the direction of progress.

According to an embodiment of the disclosure, one end of the second signal line 331 may be connected with the first signal line 321, and the opposite end of the second signal line 331 may be connected with the second ground 343. One end of the third signal line 333 may be connected with the fourth signal line 341, and the opposite end of the third signal line 333 may be connected with the first ground 323. In this case, the second signal line 331 may be shorted with the second ground 343, and the third signal line 333 is shorted with the first ground 323, but the signal transmission route changing section S2 does not interfere with normal operation due to high frequencies being transmitted.

In this case, because a length of the second signal line 331 and a length of the third signal line 333 disposed in the signal transmission route changing section S2 are formed longer than a length of a high frequency wavelength transmitted along the transmission component 300, the above may satisfy a boundary condition of electromagnetic waves being propagated. Accordingly, even if the second signal line 331 is shorted with the second ground 343 and the third signal line 333 is shorted with the first ground 323, high frequency signal transmission by the transmission component 300 may be carried out smoothly. The transmission component 300 according to an embodiment of the disclosure may form characteristic impedances of the first signal transmission section S1, the signal transmission route changing section S2, and the second signal transmission section S3 to all be substantially the same. For example, the characteristic impedances of the first signal transmission section S1, the signal transmission route changing section S2, and the second signal transmission section S3 may all be formed at about 50 ohms (Ω).

According to an embodiment of the disclosure, in order to form the characteristic impedances of the signal transmission route changing section S2 to about 50 ohms (Ω), permittivity of the dielectric layer 310 may be formed at about 3.3, loss tangent may be formed at about 0.003, thickness T may be formed at about 80 μm, and a width W2 of the second signal line 331 and the third signal line 333 may be formed at about 340 μm. In this case, a total length L of the dielectric layer 310 may be formed at about 36.5 mm, and the width W at about 6 mm.

According to an embodiment of the disclosure, in order to form the characteristic impedances of the first signal transmission section S1 to about 50 ohms (Ω), the width W1 (referring to FIG. 7) of the first signal line 321 may be formed to about 180 μm, and a thickness T1 (referring to FIG. 7) may be formed to about 80 μm. In this case, permittivity of the first signal transmission section S1 may be formed at about 3.3 same as permittivity of the signal transmission route changing section S2.

According to an embodiment of the disclosure, in order to form the characteristic impedances of the second signal transmission section S3 to about 50 ohms (Ω), the width W3 (referring to FIG. 9) of the fourth signal line 341 may be formed to about 180 μm, and the thickness T2 (referring to FIG. 9) may be formed to about 80 μm. In this case, permittivity of the second signal transmission section S3 may be formed at about 3.3 same as the permittivity of the signal transmission route changing section S2.

As described above, if the characteristic impedances of the first signal transmission section S1, the signal transmission route changing section S2, and the second signal transmission section S3 of the transmission component 300 are all formed substantially the same, the transmission component 300 may improve or minimize reflected waves by impedance discontinuities.

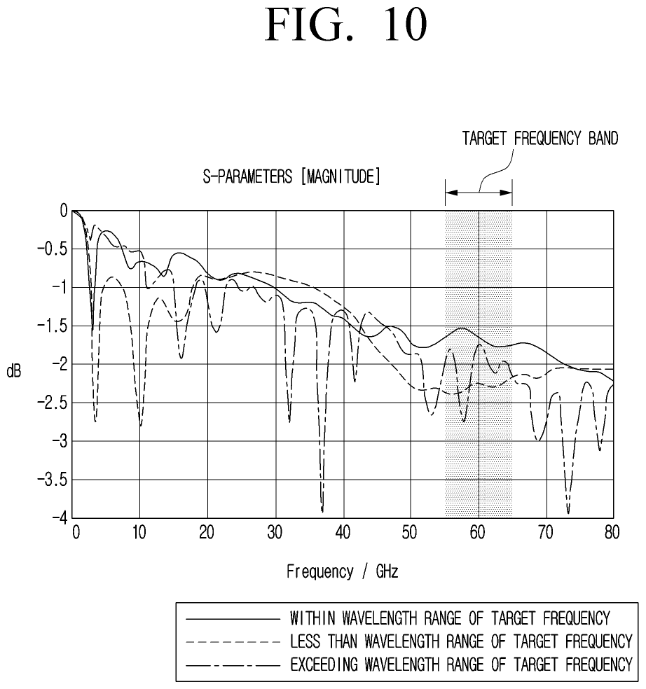

FIG. 10 is a graph illustrating a relationship between a length of a signal transmission route changing section of a transmission component and a wavelength range of a target frequency according to an embodiment of the disclosure.

The target frequency of the transmission component 300 according to an embodiment of the disclosure may be set according to a length L1 (referring to FIG. 5) of the signal transmission route changing section S2. For example, the length L1 of the signal transmission route changing section S2 may be formed within a reference range which is about 1.5 times to about 10 times with respect to the wavelength of the target frequency.

Referring to FIG. 10, a target frequency band of the transmission component 300 may be set to about 55-65 GHz. The transmission component (shown in a solid line in FIG. 10) with the length L1 of the signal transmission route changing section S2 that is within a wavelength range of the target frequency may show an insertion loss in the target frequency band of an average of about −1.8 dB.

Meanwhile, a signal transmission route changing transmission component (shown in hidden lines in FIG. 10) with the length L1 of the signal transmission route changing section S2 being less than a lower limit of the wavelength range of the target frequency may show the insertion loss in the target frequency band as an average of about −2.3 dB. As described, if the length L1 of the signal transmission route changing section is shorter than the reference range, the first signal line 321 and the first ground 323 in the first signal transmission section S1 may interact and insertion loss may be increased, and the fourth signal line 341 and the second ground 343 in the second signal transmission section S3 may interact and insertion loss may be increased.

The transmission component (shown as alternated long and short dash lines in FIG. 10) with the length L1 of the signal transmission route changing section S2 exceeding an upper limit of the wavelength range of the target frequency may show the insertion loss in the target frequency band as an average of about −2.2 dB. As described, if the length L1 of the signal transmission route changing section S2 is longer than the reference range, insertion loss may increase. In addition, distances between discontinuous surfaces (e.g., both ends of the signal transmission route changing section S2 and points at which the first ground 323 and the second ground 343 are in contact) may become further apart. Accordingly, because a frequency of standing waves generated by reflected waves is lowered, bandwidth may be reduced due to resonance occurring multiple times.

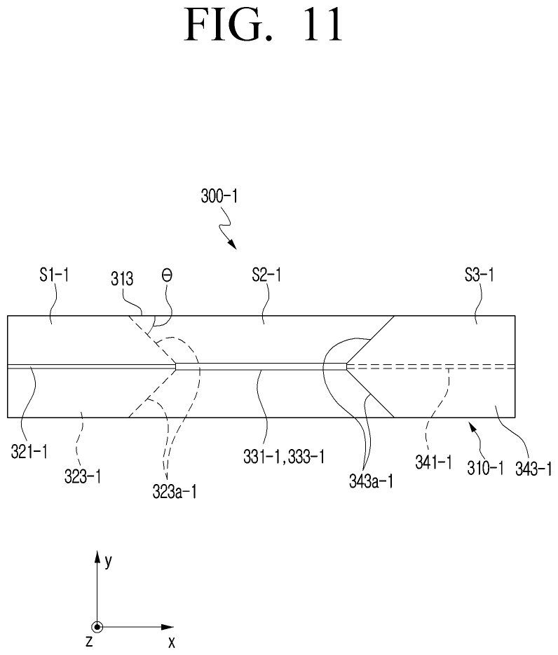

FIG. 11 is a plane view illustrating a transmission component according to an embodiment of the disclosure.

Referring to FIG. 11, the transmission component 300-1 may be consecutively disposed with a first signal transmission section S1-1, a signal transmission route changing section S2-1, and a second signal transmission section S3-1. The transmission component 300-1 may include a dielectric layer 310-1 having a length corresponding to each of the sections S1-1, S2-1, and S3-1. For example, the dielectric layer 310-1 may be a flexible printed circuit board (referring to 310 in FIG. 3).

According to an embodiment of the disclosure, the first signal transmission section S1-1 may have a microchip structure. For example, the first signal transmission section S1-1 may include a first signal line 321-1 having a narrow width on a first surface of the dielectric layer 310-1, and a first ground 323-1 having a significantly wider width than the width of the first signal line 321-1 on a second surface which is an opposite side of the first surface of the dielectric layer 310-1. For example, when the width of the first signal line 321-1 is about 180 μm, the first ground 323-1 may be formed as about 6 mm.

According to an embodiment of the disclosure, a front end 323a-1 of the first ground 323-1 may be disposed inclined in an opposite direction of the signal transmission route changing section S2-1. For example, the front end 323a-1 of the first ground 323-1 may include a pair of straight-line portions symmetrically disposed with respect to a center line along a length direction of the transmission component 300-1. The pair of straight-line portions may be respectively disposed at a designated angle (θ) range (e.g., a range from an angle exceeding 0° to about 70°) with respect to a side end 313 of the transmission component 300-1. The more the angle (θ) increases, the bandwidth may increase due to reflection in the boundary (e.g., the front end 323a-1 of the first ground 323-1) of the signal transmission route changing section S2-1 decreasing. If the angle (θ) exceeds 70°, a surface area of the first ground 323-1 may decrease. As described, if the front end 323a-1 of the first ground 323-1 includes a pair of inclined straight-line portions, the reflected waves that occur at the boundary of the first signal transmission section S1-1 and the signal transmission route changing section S2-1 may be improved or minimized.

According to an embodiment of the disclosure, the second signal transmission section S3-1 may have a microstrip structure. For example, the second signal transmission section S3-1 may include a fourth signal line 341-1 having a narrow width on a second surface of the dielectric layer 310-1, and a second ground 343-1 having a significantly wider width than the width of the fourth signal line 341-1 on the first surface of the dielectric layer 310-1. For example, if the width of the fourth signal line 341-1 is about 180 μm, the second ground 343-1 may be formed as about 6 mm.

According to an embodiment of the disclosure, a front end 343a-1 of the second ground 343-1 may be disposed to be inclined in an opposite direction of the signal transmission route changing section S2-1. For example, the front end 343a-1 of the second ground 343-1 may include a pair of straight-line portions symmetrically disposed with respect to the center line along the length direction of the transmission component 300-1. The pair of straight-line portions may be respectively disposed at the designated angle (θ) range (e.g., a range from an angle exceeding 0° to about 70°) with respect to the side end 313 of the transmission component 300-1. As described, if the front end 343a-1 of the second ground 343-1 includes a pair of inclined straight-line portions, the reflected waves that occur at the boundary of the second signal transmission section S3-1 and the signal transmission route changing section S2-1 may be improved or minimized.

According to an embodiment of the disclosure, the first signal transmission section S1-1 and the second signal transmission section S3-1 may be formed in a rough symmetry with respect to the center line which is perpendicular to the length direction of the transmission component 300-1.

According to an embodiment of the disclosure, the signal transmission route changing section S2-1 may have a parallel-plate waveguide structure. For example, the signal transmission route changing section S2-1 may include a second signal line 331-1 and a third signal line 333-1 which are respectively disposed on the first and second surfaces of the dielectric layer 310-1. The second signal line 331-1 and the third signal line 333-1 may be arranged to correspond to each other. The second signal line 331-1 and the third signal line 333-1 may have a same width, and may be formed smaller than the width of the dielectric layer 310-1.

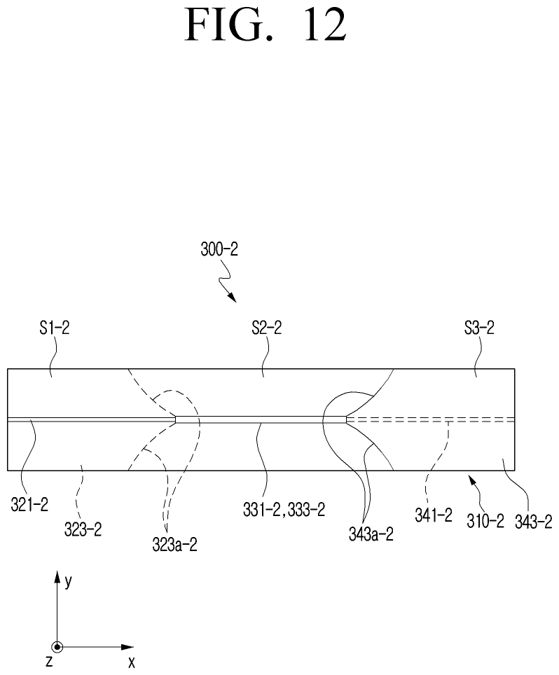

FIG. 12 is a plane view illustrating a transmission component according to an embodiment of the disclosure.

Referring to FIG. 12, a transmission component 300-2 may be consecutively disposed with a first signal transmission section S1-2, a signal transmission route changing section S2-2, and a second signal transmission section S3-2. The transmission component 300-2 may include a dielectric layer 310-2 having length corresponding to each of the sections S1-2, S2-2, and S3-2. For example, the dielectric layer 310-2 may be a flexible printed circuit board (referring to 310 in FIG. 3).

According to an embodiment of the disclosure, the first signal transmission section S1-2 may have a microstrip structure. For example, the first signal transmission section S1-2 may include a first signal line 321-2 having a narrow width on a first surface of the dielectric layer 310-2, and a first ground 323-2 having a significantly wider width than the width of the first signal line 321-2 on a second surface which is an opposite side of the first surface of the dielectric layer 310-2. For example, if the width of the first signal line 321-2 is about 180 μm, the width of the first ground 323-2 may be formed as about 6 mm.

According to an embodiment of the disclosure, a front end 323a-2 of the first ground 323-2 may be formed as a pair of curved portions disposed to be inclined in an opposite direction of the signal transmission route changing section S2-2. The pair of curved portions may be symmetrically disposed with respect to a center line along a length direction of the transmission component 300-2. The pair of curved portions may respectively have a constant curvature to be protruded toward a center line of the transmission component 300-2.

According to an embodiment of the disclosure, the second signal transmission section S3-2 may have a microstrip structure. For example, the second signal transmission section S3-2 may include a fourth signal line 341-2 having a narrow width on a second surface of the dielectric layer 310-2, and a second ground 343-2 having a significantly wider width than the width of the fourth signal line 341-2 on the first surface of the dielectric layer 310-2. For example, if the width of the fourth signal line 341-2 is about 180 μm, the width of the second ground 343-2 may be formed as about 6 mm.

According to an embodiment of the disclosure, a front end 343a-2 of the second ground 343-2 may be formed as a pair of curved portions disposed to be inclined in the opposite direction of the signal transmission route changing section S2-2. The pair of curved portions may be symmetrically disposed with respect to a center line along a length direction of the transmission component 300-2. The pair of curved portions may respectively have a constant curvature to be protruded toward the center line of the transmission component 300-2. For example, the front end 323a-2 of the first ground 323-2 and the front end 343a-2 of the second ground 343-2 may be symmetrically disposed with respect to the center line along the length direction of the transmission component 300-2.

According to an embodiment of the disclosure, the first signal transmission section S1-2 and the second signal transmission section S3-2 may be formed in a rough symmetry with respect to the center line which is perpendicular to the length direction of the transmission component 300-2.

According to an embodiment of the disclosure, the signal transmission route changing section S2-2 may have a parallel-plate waveguide structure. For example, the signal transmission route changing section S2-2 may include a second signal line 331-2 and a third signal line 333-2 which are respectively disposed on the first and second surfaces of the dielectric layer 310-2. The second signal line 331-2 and the third signal line 333-2 may be arranged to correspond to each other. The second signal line 331-2 and the third signal line 333-2 may have a substantially same width, and may be formed smaller than the width of the dielectric layer 310-2.

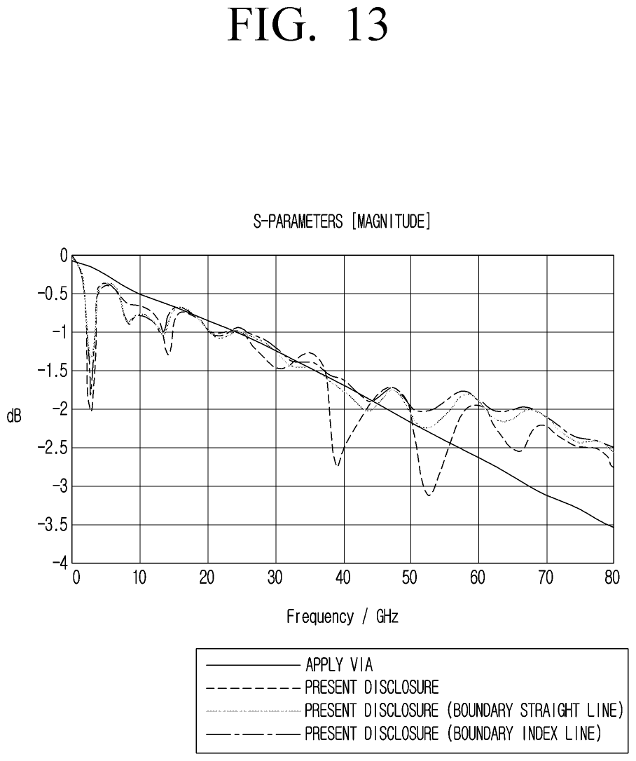

FIG. 13 is a graph illustrating a comparison of insertion loss between a transmission component and a transmission component applied with via according to an embodiment of the disclosure.

Referring to FIG. 13, the transmission component 300 (referring to FIG. 6) in which the front ends 323a and 343a of the first and second grounds 323 and 343 are perpendicular to the length direction of the transmission component may show an insertion loss in the target frequency (e.g., about 60 GHZ) of about-1.9 dB (shown as hidden lines in FIG. 13). The transmission component 300-1 (referring to FIG. 11) in which the front ends 323a-1 and 343a-1 of the first and second grounds 323-1 and 343-1 respectively have a pair of inclined straight-line portions may show an insertion loss in the target frequency (e.g., about 60 GHZ) of about-1.86 dB (shown as alternated long and short dash lines in FIG. 13). The transmission component 300-2 (referring to FIG. 12) in which the front ends 323a-2 and 343a-2 of the first and second grounds 323-2 and 343-2 respectively have a pair of inclined straight-line portions may show an insertion loss in the target frequency (e.g., about 60 GHz) of about-1.86 dB (shown as alternated long and short dash lines in FIG. 13). The transmission component applied with via may show an insertion loss in the target frequency (e.g., about 60 GHZ) of about 2.64 dB (shown as a solid line in FIG. 13).

If the transmission components 300, 300-1, and 300-2 according to embodiments of the disclosure and the transmission component applied with via are formed as same lengths an compared, the transmission components 300, 300-1, and 300-2 according to embodiments of the disclosure show that the insertion loss in the target frequency may be improved by about 0.7 dB or more compared to the transmission component applied with via.

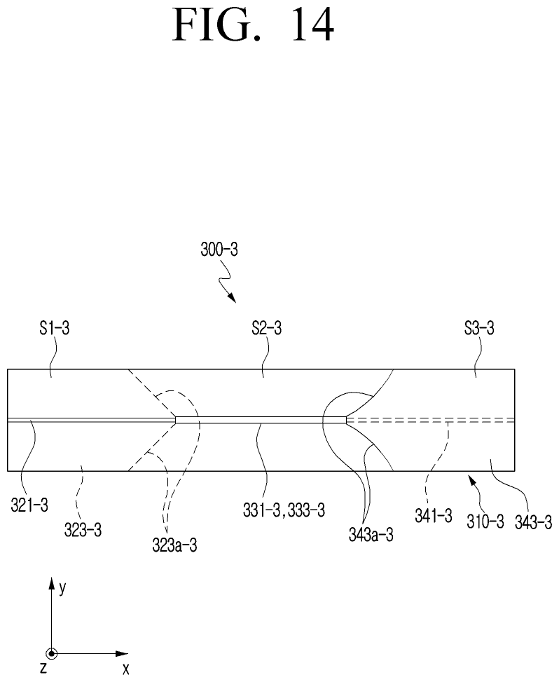

FIG. 14 is a plane view illustrating a transmission component according to an embodiment of the disclosure.

Referring to FIG. 14, the transmission component 300-3 may be consecutively disposed with a first signal transmission section S1-3, a signal transmission route changing section S2-3, and a second signal transmission section S3-3. The transmission component 300-3 may include a dielectric layer 310-3 having a length corresponding to each of the sections S1-3, S2-3, and S3-3. For example, the dielectric layer 310-3 may be a flexible printed circuit board (referring to 310 in FIG. 3).

According to an embodiment of the disclosure, the first signal transmission section S1-3 may have a microstrip structure. For example, the first signal transmission section S1-3 may include a first signal line 321-3 having a narrow width on a first surface of the dielectric layer 310-3, and a first ground 323-3 having a significantly wider width than the width of the first signal line 321-3 on a second surface which is an opposite side of the first surface of the dielectric layer 310-3. For example, if the width of the first signal line 321-3 is about 180 μm, the width of the first ground 323-3 may be formed as about 6 mm.

According to an embodiment of the disclosure, a front end 323a-3 of the first ground 323-3 may be disposed to be inclined in an opposite direction of a signal transmission route changing section S2-3. For example, the front end 323a-3 of the first ground 323-3 may include a pair of straight-line portions symmetrically disposed with respect to a center line along a length direction of the transmission component 300-3. The pair of straight-line portions may be respectively disposed at a constant angle range (e.g., a range from an angle exceeding 0° to about 70°) with respect to a side end of the transmission component.

According to an embodiment of the disclosure, the second signal transmission section S3-3 may have a microstrip structure. For example, the second signal transmission section S3-3 may include a fourth signal line 341-3 having a narrow width on a second surface of the dielectric layer 310-3, and a second ground 343-3 having a significantly wider width than the width of the fourth signal line 341-3 on a first surface of the dielectric layer 310-3. For example, if the width of the fourth signal line 341-3 is about 180 μm, the width of the second ground 343-3 may be formed as about 6 mm.

According to an embodiment of the disclosure, a front end 343a-3 of the second ground 343-3 may be formed as a pair of curved portions disposed to be inclined toward an opposite direction of the signal transmission route changing section S2-3. The pair of curved portions may be symmetrically disposed with respect to a center line along a length direction of the transmission component 300-3. The pair of curved portions may respectively have a constant curvature to be protruded toward the center line of the transmission component 300-3. The front end 323a-3 of the first ground 323-3 may include a pair of straight-line portions, and a front end 343a-3 of the second ground 343-3 may include a pair of curved portions. Accordingly, the front end 323a-3 of the first ground 323-3 and the front end 343a-3 of the second ground 343-3 may be asymmetrical with respect to the center line along the length direction of the transmission component 300-2.

According to an embodiment of the disclosure, the signal transmission route changing section S2-3 may have a parallel-plate waveguide structure. For example, the signal transmission route changing section S2-3 may include a second signal line 331-3 and a third signal line 333-3 which are respectively disposed on the first and second surfaces of the dielectric layer 310-3. The second signal line 331-3 and the third signal line 333-3 may be arranged to correspond to each other. The second signal line 331-3 and the third signal line 333-3 may have a substantially same width, and may be formed smaller than the width of the dielectric layer 310-3.

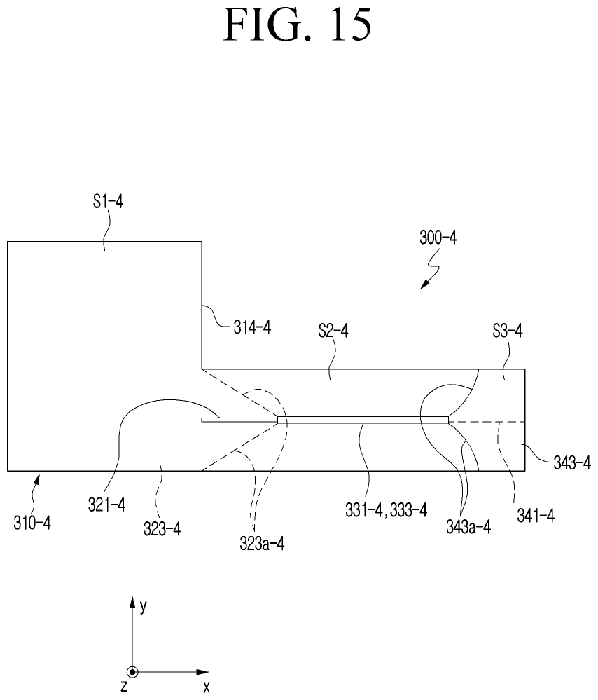

FIG. 15 is a plane view illustrating a transmission component according to an embodiment of the disclosure.

Referring to FIG. 15, the transmission component 300-4 may be consecutively disposed with a first signal transmission section S1-4, a signal transmission route changing section S2-4, and a second signal transmission section S3-4. The transmission component 300-4 may include a dielectric layer 310-4 having a length corresponding to each of the sections S1-4, S2-4, and S3-4. For example, the dielectric layer 310-4 may be a flexible printed circuit board (referring to 310 in FIG. 3).

According to an embodiment of the disclosure, the first signal transmission section S1-4 may have a microstrip structure. For example, the first signal transmission section S1-4 may include a first signal line 321-4 having a narrow width on a first surface of the dielectric layer 310-4, and a first ground 323-4 having a significantly wider width than the width of the first signal line 321-4 on a second surface which is an opposite side of the first surface of the dielectric layer 310-4.

According to an embodiment of the disclosure, the dielectric layer 310-4 may include an extension portion 314-4 extending from one side of the first signal transmission section S1-4. The first ground 323-4 may secure electrical security of the transmission component 300-4 due to a size thereof being increased to correspond to the extension portion 314-4.

According to an embodiment of the disclosure, a front end 323a-4 of the first ground 323-4 may be disposed to be inclined in an opposite direction of the signal transmission route changing section S2-4. For example, the front end 323a-4 of the first ground 323-4 may include a pair of straight-line portions symmetrically disposed with respect to a center line along a length direction of the transmission component 300-4. The pair of straight-line portions may be respectively disposed at a constant angle range (e.g., a range from an angle exceeding 0° to about 70°) with respect to a side end of the transmission component 300-4.

According to an embodiment of the disclosure, a front end 343a-4 of a second ground 343-4 may be formed as a pair of curved portions disposed to be inclined in an opposite direction of the signal transmission route changing section S2-4. The pair of curved portions may be symmetrically disposed with respect to the center line along the length direction of the transmission component 300-4. The pair of curved portions may respectively have a constant curvature to be protruded toward the center line of the transmission component 300-4. The front end 323a-4 of the first ground 323-4 may include a pair of straight-line portions, and the front end 343a-4 of the second ground 343-4 may include a pair of curved portions. Accordingly, the front end 323a-3 of the first ground 323-3 and the front end 343a-3 of the second ground 343-3 may be asymmetrical with respect to the center line along the length direction of the transmission component 300-4.

According to an embodiment of the disclosure, the front end 323a-3 of the first ground 323-3 and the front end 343a-3 of the second ground 343-3 may be formed symmetrically with each other. For example, the front end 323a-4 of the first ground 323-4 may include a pair of curved portions like the front end 343a-4 of the second ground 343-4. For example, the front end 343a-4 of the second ground 343-4 may include a pair of straight-line portions like the front end 323a-4 of the first ground 323-4.

According to an embodiment of the disclosure, the first signal transmission section S1-4 may be formed in a rough asymmetry with the second signal transmission section S3-4 due to the extension portion 314-4 respect to the center line which is perpendicular to the length direction of the transmission component 300-4.

According to an embodiment of the disclosure, the signal transmission route changing section S2-4 may have a parallel-plate waveguide structure. For example, the signal transmission route changing section S2-4 may include a second signal line 331-4 and a third signal line 333-4 which are respectively disposed at the first and second surfaces of the dielectric layer 310-4. The second signal line 331-4 and the third signal line 333-4 may be arranged to correspond to each other. The second signal line 331-4 and the third signal line 333-4 may have a substantially same width, and may be formed smaller than the width of the dielectric layer 310-4.

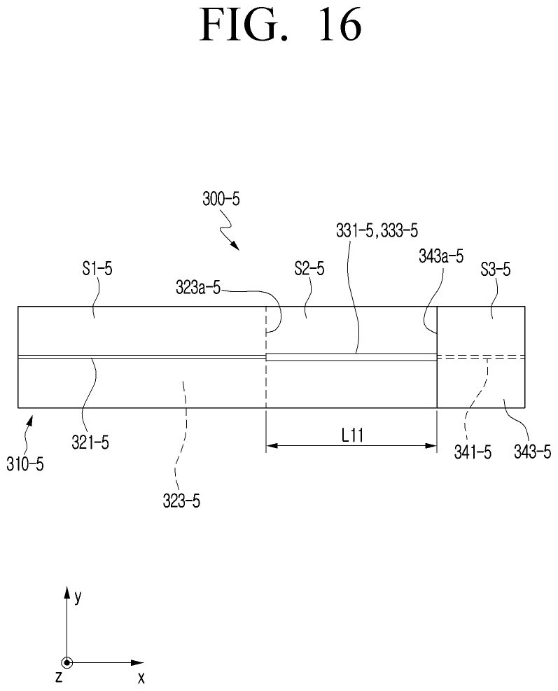

FIG. 16 is a plane view illustrating a transmission component according to an embodiment of the disclosure.

Referring to FIG. 16, the transmission component 300-5 may be consecutively disposed with a first signal transmission section S1-5, a signal transmission route changing section S2-5, and a second signal transmission section S3-5. The transmission component 300-5 may include a dielectric layer 310-5 having a length corresponding to each of the sections S1-5, S2-5, and S3-5. For example, the dielectric layer 310-5 may be a flexible printed circuit board (referring to 310 in FIG. 3).

According to an embodiment of the disclosure, the first signal transmission section S1-5 may have a microstrip structure. For example, the first signal transmission section S1-5 may include a first signal line 321-5 having a narrow width on a first surface of the dielectric layer 310-5, and a first ground 323-5 having a significantly wider width than the width of the first signal line 321-5 on a second surface which is an opposite side of the first surface of the dielectric layer 310-5. For example, if the width of the first signal line 321-5 is about 180 μm, the width of the first ground 323-5 may be formed as about 6 mm. A front end 323a-5 of the first ground 323-5 may be formed to be perpendicular to a length direction of the dielectric layer 310-5.

According to an embodiment of the disclosure, the second signal transmission section S3-5 may have a microstrip structure. For example, the second signal transmission section S3-5 may include a fourth signal line 341-5 having a narrow width on a second surface of the dielectric layer 310-5, and a second ground 343-5 having a significantly wider width than the width of the fourth signal line 341-5 on the first surface of the dielectric layer 310-5. For example, if the width of the fourth signal line 341-5 is about 180 μm, the width of the second ground 343-5 may be formed as about 6 mm. A front end 343a-5 of the second ground 343-5 may be formed to be perpendicular to the length direction of the dielectric layer 310-5.

According to an embodiment of the disclosure, the signal transmission route changing section S2-5 may have a parallel-plate waveguide structure. For example, the signal transmission route changing section S2-5 may include a second signal line 331-5 and a third signal line 333-5 which are respectively disposed at the first and second surfaces of the dielectric layer 310-5. The second signal line 331-5 and the third signal line 333-5 may be arranged to correspond to each other. The second signal line 331-5 and the third signal line 333-5 may have a substantially same width, and may be formed smaller than the width of the dielectric layer 310-5.

According to an embodiment of the disclosure, the first signal transmission section S1-5 and the second signal transmission section S3-5 may be formed in a rough asymmetry with respect to the center line which is perpendicular to the length direction of the transmission component 300-5. For example, a length of the first signal transmission section S1-5 may be formed longer than a length of the second signal transmission section S3-5. In this case, a length L11 of the signal transmission route changing section S2-5 may be formed to be 1.5 times to 10 times of the wavelength of the target frequency of the transmission component 300-5. If a condition of the length L11 of the signal transmission route changing section S2-5 is satisfied, the insertion loss may be reduced by minimizing the reflected waves of the transmission component 300-5 even when the length of the first signal transmission section S1-5 and the length of the second signal transmission section S3-5 are configured differently.

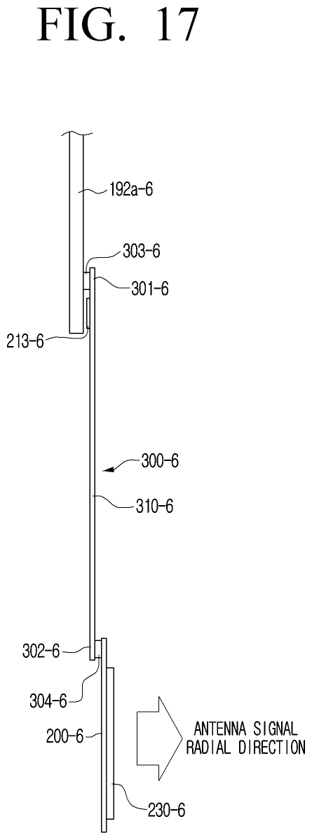

FIG. 17 is a diagram illustrating an antenna being connected to a transmission component through a connector according to an embodiment of the disclosure.

Referring to FIG. 17, the transmission component 300-6 may be included in an electronic device 100-6 to transmit signals between a first printed circuit board 192a-6 and a third printed circuit board 200-6 on which the antenna 230-6 is disposed. A first side portion 301-6 of the transmission component 300-6 may be connected to the first printed circuit board 192a-6, and a second side portion 302-6 of the transmission component 300-6 may be connected to a third printed circuit board 200-6.

According to an embodiment of the disclosure, the first printed circuit board 192a-6 and the third printed circuit board 200-6 may be a flexible printed circuit board so as to reduce the thickness of the electronic device (e.g., referring to 100 in FIG. 2), but is not limited thereto. For example, the first printed circuit board 192a-6 and the third printed circuit board 200-6 may be a printed circuit board formed of a material with a thickness thicker than the flexible printed circuit board and harder.

According to an embodiment of the disclosure, at the first side portion 301-6 of the transmission component 300-6, a first connector 303-6 which is electrically connected with the first printed circuit board 192a-6 may be provided. At the first side portion 301-6 of the transmission component 300-6, an RF IC 213-6 may be disposed. In this case, the first connector 303-6 and/or the RF IC 213-6 may be provided on the first printed circuit board 192a-6.

According to an embodiment of the disclosure, at the second side portion 302-6 of the transmission component 300-6, a second connector 304-6 electrically connected with the third printed circuit board 200-6 may be provided. The antenna 230-6 provided on the third printed circuit board 200-6 may include an antenna pattern electrically connected with the transmission component 300-6. For example, the antenna 230-6 may be an mmWave antenna which transmits and receives signals in a millimeter wave (e.g., 30 GHz-300 GHz) band.

For example, one end of the first signal line (e.g., referring to 321 in FIG. 4) of the transmission component 300-6 may be connected with the second connector 304-6 disposed at the second side portion 302-6 of a dielectric layer 310-6. The second connector 304-6 may be connected with the mm Wave antenna 230-6 through the third printed circuit board 200-6. Accordingly, the first signal line (e.g., referring to 321 in FIG. 4) may be electrically connected with the mm Wave antenna 230-6.

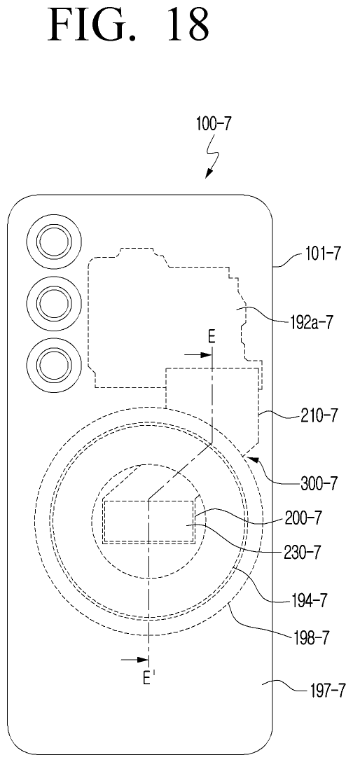

FIG. 18 is a diagram illustrating a back surface cover being coupled to a housing of an electronic device according to an embodiment of the disclosure.

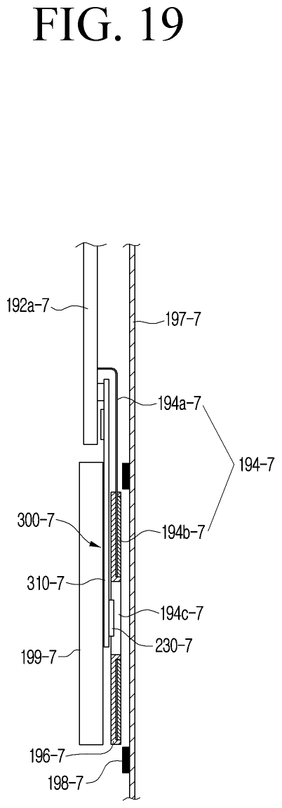

FIG. 19 is a diagram illustrating a cross-sectional view taken along line E-E′ shown in FIG. 18 according to an embodiment of the disclosure.

Referring to FIGS. 18 and 19, the electronic device 100-7 according to an embodiment of the disclosure may include a wireless charging coil portion 194-7. For example, the wireless charging coil portion 194-7 may be disposed between the back surface cover 197-7 which can be coupled at a rear direction of a housing 101-7 and a transmission component 300-7.

According to an embodiment of the disclosure, the wireless charging coil portion 194-7 may include a base substrate 194a-7 (e.g., flexible printed circuit board) and a conductive pattern 194b-7 formed on the base substrate 194a-7. The base substrate 194a-7 may be electrically connected with a first printed circuit board 192a-7.

According to an embodiment of the disclosure, the wireless charging coil portion 194-7 may be coupled to a support member 196-7. In this case, the wireless charging coil portion 194-7 may be isolated from the transmission component 300-7 by the support member 196-7. For example, the support member 196-7 may have a rough ring shape so as to correspond to the conductive pattern 194b-7 of the wireless charging coil portion 194-7. An antenna 230-7 disposed at one side 200-7 of the transmission component 300-7 may transmit and receive antenna signals to the outside of the electronic device 100-7 through an opening 194c-7 provided roughly at a center of the wireless charging coil portion 194-7.

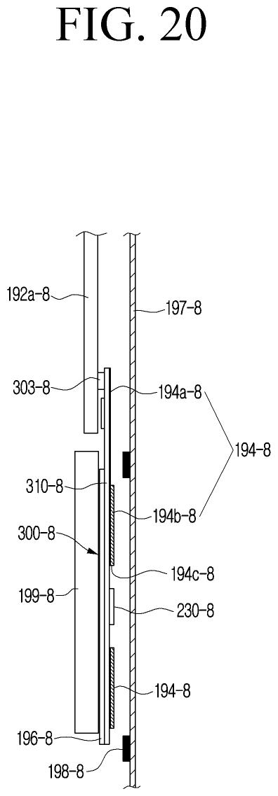

According to an embodiment of the disclosure, the support member 196-7 may include a structure stacked with a magnetic and shielding layer and a heat radiating layer. For example, the magnetic and shielding layer of the support member 196-7 may include a ferrite sheet, and the heat radiating layer may include a graphite sheet. The support member 196-7 may improve on heat which is generated in the conductive pattern 194b-7 (194b-8 in FIG. 20) when performing wireless charging being passed toward a battery 310-7. In this case, the transmission component 300-7 may be positioned between the wireless charging coil portion 194-7 and a battery 199-7.

According to an embodiment of the disclosure, the back surface cover 197-7 may be coupled with a magnet 198-7 having a rough ring shape at an inside surface thereof. For example, the magnet 198-7 and the wireless charging coil portion 194-7 may be disposed in a concentric circle. In this case, an inner diameter of the magnet 198-7 may be larger than an outer diameter of the wireless charging coil portion 194-7.

For example, a wireless charging device (not shown) which can charge the battery 199-7 of the electronic device 100-7 may include a magnet (not shown) with which an attractive force with the magnet 198-7 can be exerted at a wireless charging position. In this case, the electronic device 100-7 may be stably attached to the wireless charging position of the wireless charging device (not shown) by the magnet 198-7. For example, at an outer surface of the back surface cover 197-7 of the electronic device 100-7, an accessory, such as a card wallet (not shown) or a finger grip (not shown) may be attached or removed using magnetic force of the magnet 198-7. In this case, the card wallet and the finger grip may be embedded with a magnet (not shown) with which an attractive force with the magnet 198-7 can be exerted.

FIG. 20 is a diagram illustrating an antenna and a wireless charging coil portion are disposed together on a flexible printed circuit board included in a transmission component of an electronic device according to an embodiment of the disclosure.

Referring to FIG. 20, the wireless charging coil portion 194-8 may be formed integrally with the flexible printed circuit board 310-8 as a base substrate 194a-8 is stacked on the flexible printed circuit board 310-8 included in the transmission component 300-8. In this case, the base substrate 194a-8 may be electrically connected with a first printed circuit board 192a-8 through a connector 303-8.

According to an embodiment of the disclosure, the antenna 230-8 disposed on a top surface of the flexible printed circuit board 310-8 may transmit and receive antenna signals to the outside of the electronic device 100-7 through an opening 194c-8 provided roughly at a center of the wireless charging coil portion 194-8.

According to an embodiment of the disclosure, a support member 196-8 may be disposed between the transmission component 300-8 and a battery 199-8. The support member 196-8 may include a structure stacked with the magnetic and shielding layer (e.g., ferrite sheet) and/or the heat radiating layer (e.g., graphite sheet) similarly with the support member 196-7 described with reference to FIG. 19. For example, the support member 196-8 may be stacked at a bottom surface of the flexible printed circuit board 310-8. For example, the support member 196-8 may be formed integrally with the flexible printed circuit board 310-8.

According to an embodiment of the disclosure, a back surface cover 197-8 may be coupled with a magnet 198-8 having a rough ring shape at an inside surface thereof. For example, the magnet 198-8 and the wireless charging coil portion 194-8 may be disposed in a concentric circle. In this case, an inner diameter of the magnet 198-8 may be larger than an outer diameter of the wireless charging coil portion 194-8.

According to an embodiment of the disclosure, the transmission components 300, 300-1, 300-2, 300-3, 300-4, and 300-5 may include flexible printed circuit boards 310, 310-1, 310-2, 310-3, 310-4, and 310-5 including first signal transmission sections S1, S1-1, S1-2, S1-3, S1-4, and S1-5, second signal transmission sections S3, S3-1, S3-2, S3-3, S3-4, and S3-5, and signal transmission route changing sections S2, S2-1, S2-2, S2-3, S2-4, and S2-5 disposed between the first signal transmission sections S1, S1-1, S1-2, S1-3, S1-4, and S1-5 and the second signal transmission sections S3, S3-1, S3-2, S3-3, S3-4, and S3-5, first signal lines 321, 321-1, 321-2, 321-3, 321-4, and 321-5 provided on a first surface of the flexible printed circuit board and disposed in the first signal transmission section, first grounds 323, 323-1, 323-2, 323-3, 323-4, and 323-5 provided on a second surface opposite to the first surface of the flexible printed circuit board and disposed in the first signal transmission section, second signal lines 331, 331-1, 331-2, 331-3, 331-4, and 331-5 provided on the first surface of the flexible printed circuit board to be disposed in the signal transmission route change section, and wherein one end of the second signal line is connected to the first signal line, third signal lines 333, 333-1, 333-2, 333-3, 333-4, and 333-5 provided on the second surface of the flexible printed circuit board to be disposed in the signal transmission route change section, and wherein one end of the third signal line is connected to the first ground, fourth signal lines 341, 341-1, 341-2, 341-3, 341-4, and 341-5 provided on the second surface of the flexible printed circuit board to be disposed in the second signal transmission section, and wherein one end of the fourth signal line is connected to other end of the third signal line, and second grounds 343, 343-1, 343-2, 343-3, 343-4, and 343-5 provided on the first surface of the flexible printed circuit board to be disposed in the second signal transmission section, and wherein one end of the second ground is connected to other end of the second signal line.

According to an embodiment of the disclosure, the lengths L1 and L11 of the signal transmission route changing sections S2, S2-1, S2-2, S2-3, S2-4, and S2-5 may be configured to be 1.5 times to 10 times of the wavelength of the target frequency of the transmission component.

According to an embodiment of the disclosure, each of characteristic impedances of the first signal transmission sections S1, S1-1, S1-2, S1-3, S1-4, and S1-5, the signal transmission route changing sections S2, S2-1, S2-2, S2-3, S2-4, and S2-5, and the second signal transmission sections S3, S3-1, S3-2, S3-3, S3-4, and S3-5 may be configured to be same.

According to an embodiment of the disclosure, the second signal lines 331, 331-1, 331-2, 331-3, 331-4, and 331-5 and the third signal lines 333, 333-1, 333-2, 333-3, 333-4, and 333-5 may be configured to be smaller than the width of the flexible printed circuit board.

According to an embodiment of the disclosure, the width of the first signal lines 321, 321-1, 321-2, 321-3, 321-4, and 321-5 may be configured to be smaller than the widths of the second signal line and the third signal line. The width of the fourth signal lines 341, 341-1, 341-2, 341-3, 341-4, and 341-5 may be configured to be smaller than the widths of the second signal line and the third signal line.

According to an embodiment of the disclosure, the width of the first signal lines 321, 321-1, 321-2, 321-3, 321-4, and 321-5 and the width of the fourth signal lines 341, 341-1, 341-2, 341-3, 341-4, and 341-5 may be configured to be substantially the same.

According to an embodiment of the disclosure, the second signal lines 331, 331-1, 331-2, 331-3, 331-4, and 331-5 and the third signal lines 333, 333-1, 333-2, 333-3, 333-4, and 333-5 may be configured to have a substantially same width.

According to an embodiment of the disclosure, the front end of the first grounds 323, 323-1, 323-2, 323-3, 323-4, and 323-5 may be configured to be positioned at a boundary of the first signal transmission section and the signal transmission route changing section. The front end of the second grounds 343, 343-1, 343-2, 343-3, 343-4, and 343-5 may be configured to be positioned at a boundary of the signal transmission route changing section and the second signal transmission section.

According to an embodiment of the disclosure, the front end of the first grounds 323 and 323-5 may be configured to be perpendicular to the length direction of the flexible printed circuit board. The front end of the second grounds 343 and 343-5 may be configured to be perpendicular to the length direction of the flexible printed circuit board.

According to an embodiment of the disclosure, the front end of the first ground 323-1 may be configured to be between 0 degree to 70 degrees in an opposite direction of the signal transmission route changing section with respect to a line perpendicular to the length direction of the flexible printed circuit board. The front end of the second ground 343-1 may be configured to be between 0 degree to 70 degrees in the opposite direction of the signal transmission route changing section with respect to the line perpendicular line to the length direction of the flexible printed circuit board.

According to an embodiment of the disclosure, the front end of the first ground 323-1 may include a first straight-line portion and a second straight-line portion inclined in an opposite direction of the signal transmission route changing section. The front end of the second ground 343-1 may include a third straight-line portion and a fourth straight-line portion inclined in the opposite direction of the signal transmission route changing section.

According to an embodiment of the disclosure, the front end of the first ground 323-2 may include a first curved portion and a second curved portion inclined in a defined curvature in an opposite direction of the signal transmission route changing section. The front end of the second ground 343-2 may include a third curved portion and a fourth curved portion inclined in the defined curvature in the opposite direction of the signal transmission route changing section.

According to an embodiment of the disclosure, the front end of the first grounds 323-3 and 323-4 may include a fifth straight-line portion and a sixth straight-line portion inclined in an opposite direction of the signal transmission route changing section. The front end of the second grounds 343-3 and 343-4 may include a fifth curved portion and a sixth curved portion inclined in a defined curvature in the opposite direction of the signal transmission route changing section.

According to an embodiment of the disclosure, the first signal transmission sections S1, S1-1, and S1-2 and the second signal transmission section S3, S3-1, and S3-2 may be configured symmetrically.

According to an embodiment of the disclosure, the first signal transmission sections S1-3, S1-4, and S1-5 and the second signal transmission sections S3-3, S3-4, and S3-5 may be configured asymmetrically.

According to an embodiment of the disclosure, the first signal lines 321, 321-1, 321-2, 321-3, 321-4, and 321-5 may be configured to be disposed on a same axis as the second signal line. The fourth signal lines 341, 341-1, 341-2, 341-3, 341-4, and 341-5 may be configured to be disposed on a same axis as the third signal line.

According to an embodiment of the disclosure, the flexible printed circuit board 310 may include an extension portion 310a extending from the first signal transmission section. The extension portion 310a may include the antenna 230 connected with the first signal line.

According to an embodiment of the disclosure, the antenna 230 may include the mm Wave antenna.

According to an embodiment of the disclosure, the electronic device 100 may include the housing 101, the printed circuit board 192a disposed in the housing, the antenna 230, and the transmission component including the flexible printed circuit board 310 divided into the first signal transmission section S1 positioned at one side of the antenna 230, the signal transmission route changing section S2 positioned at one side of the first signal transmission section, and the second signal transmission section S3 positioned at one side of the signal transmission route changing section. Each of the first signal transmission section and the second signal transmission section may include a first micro stripline structure. The signal transmission route changing section may include the parallel-plate waveguide structure which supports the transverse electromagnetic mode (TEM mode).

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A transmission component comprising:
a flexible printed circuit board including:
a first signal transmission section,
a second signal transmission section, and
a signal transmission route changing section disposed between the first signal transmission section and the second signal transmission section;
a first signal line provided on a first surface of the flexible printed circuit board and disposed in the first signal transmission section;
a first ground provided on a second surface opposite to the first surface of the flexible printed circuit board and disposed in the first signal transmission section;
a second signal line provided on the first surface of the flexible printed circuit board to be disposed in the signal transmission route change section, wherein one end of the second signal line is connected to the first signal line;
a third signal line provided on the second surface of the flexible printed circuit board to be disposed in the signal transmission route change section, wherein one end of the third signal line is connected to the first ground;
a fourth signal line provided on the second surface of the flexible printed circuit board to be disposed in the second signal transmission section, wherein one end of the fourth signal line is connected to other end of the third signal line; and
a second ground provided on the first surface of the flexible printed circuit board to be disposed in the second signal transmission section, wherein one end of the second ground is connected to other end of the second signal line.

2. The transmission component of claim 1, wherein a length of the signal transmission route changing section is configured to be 1.5 times to 10 times of a wavelength of a target frequency.

3. The transmission component of claim 1, wherein each of characteristic impedances of the first signal transmission section, the second signal transmission section, and the signal transmission route changing section are configured to be same.

4. The transmission component of claim 1, wherein the second signal line and the third signal line are disposed at positions corresponding to each other.

5. The transmission component of claim 4,
wherein a width of the first signal line is smaller than a width of the second signal line and the third signal line, and
wherein a width of the fourth signal line is smaller than a width of the second signal line and the third signal line.

6. The transmission component of claim 5, wherein the width of the first signal line and the width of the fourth signal line are configured to be same.

7. The transmission component of claim 4, wherein the second signal line and the third signal line are configured to have a same width.

8. The transmission component of claim 1,
wherein a front end of the first ground is positioned at a boundary of the first signal transmission section and the signal transmission route changing section, and
wherein a front end of the second ground is positioned at a boundary of the signal transmission route changing section and the second signal transmission section.

9. The transmission component of claim 8,
wherein the front end of the first ground is perpendicular to a length direction of the flexible printed circuit board, and
wherein the front end of the second ground is perpendicular to the length direction of the flexible printed circuit board.

10. The transmission component of claim 9,
wherein the front end of the first ground is configured to be between 0 degree to 70 degrees in an opposite direction of the signal transmission route changing section with respect to a line perpendicular to the length direction of the flexible printed circuit board, and
wherein the front end of the second ground is configured to be between 0 degree to 70 degrees in the opposite direction of the signal transmission route changing section with respect to the line perpendicular line to the length direction of the flexible printed circuit board.

11. The transmission component of claim 8,
wherein the front end of the first ground comprises:
a first straight-line portion and a second straight-line portion inclined in an opposite direction of the signal transmission route changing section, and
wherein the front end of the second ground comprises:
a third straight-line portion and a fourth straight-line portion inclined in the opposite direction of the signal transmission route changing section.

12. The transmission component of claim 8,
wherein the front end of the first ground comprises:
a first curved portion and a second curved portion inclined in a defined curvature in an opposite direction of the signal transmission route changing section, and
wherein the front end of the second ground comprises:
a third curved portion and a fourth curved portion inclined in the defined curvature in the opposite direction of the signal transmission route changing section.

13. The transmission component of claim 8,
wherein the front end of the first ground comprises:
a fifth straight-line portion and a sixth straight-line portion inclined in an opposite direction of the signal transmission route changing section, and
wherein the front end of the second ground comprises:
a fifth curved portion and a sixth curved portion inclined in a defined curvature in the opposite direction of the signal transmission route changing section.

14. The transmission component of claim 4,
wherein the first signal line is configured to be disposed on a same axis as the second signal line, and
wherein the fourth signal line is configured to be disposed on a same axis as the third signal line.

15. The transmission component of claim 1,
wherein the flexible printed circuit board further comprises an extension portion extending from the first signal transmission section,
wherein an antenna connected to the first signal line is disposed on the extension portion, and
wherein the antenna comprises a mm Wave antenna.

16. The transmission component of claim 15, wherein the first signal transmission section is formed in a rough asymmetry with the second signal transmission section due to the extension portion with respect to a center line which is perpendicular to a length direction of the transmission component.

17. The transmission component of claim 1, wherein a length of the first signal transmission section is formed longer than a length of the second signal transmission section.

18. The transmission component of claim 2, wherein, if a condition of the length of the signal transmission route changing section is satisfied, insertion loss is reduced by minimizing reflected waves of the transmission component even when the length of the first signal transmission section and the length of the second signal transmission section are configured differently.

19. An electronic device comprising:
a housing;
an antenna; and
a transmission component including a flexible printed circuit board on which an antenna is disposed and which is divided into a first signal transmission section disposed at one side of the antenna, a signal transmission route changing section disposed at one side of the first signal transmission section, and a second signal transmission section disposed at one side of the signal transmission route changing section,
wherein each of the first signal transmission section and the second signal transmission section include a first microstrip line structure, and
wherein the signal transmission route changing section includes a parallel-plate waveguide structure which supports a transverse electromagnetic (TEM) mode.

20. The electronic device of claim 19, wherein a length of the signal transmission route changing section is configured to be 1.5 times to 10 times of a wavelength of a target frequency.
